(19) United States
(12) Patent Application Publication
(10) Pub. No.: US 2012/0048198 A1
(43) Pub. Date: Mar. 1, 2012

(54) VAPOR PHASE GROWTH APPARATUS

(75) Inventors: Yuya Yamaoka, Tokyo (JP); Kosuke Uchiyama, Tokyo (JP)

(73) Assignees: TN EMC Ltd., Tama-city, Tokyo (JP); Taiyo Nippon Sanso Coporation, Tokyo (JP)

(21) Appl. No.: 13/318,890

(22) PCT Filed: May 14, 2010
(86) PCT No.: PCT/JP2010/058185

§ 371 Date: Nov. 4, 2011

(30) Foreign Application Priority Data
May 22, 2009 (JP) 2009-123662

(51) Int. Cl. H01L 21/363; C23C 16/46

(52) U.S. Cl. 118/725

(57) ABSTRACT

Disclosed is a rotation/revolution type vapor phase growth apparatus capable of increasing the area of a semiconductor thin film that can be vapor-phase grown at a time, without upsizing a susceptor or the like. The vapor phase growth apparatus is a horizontal vapor phase growth apparatus having a rotation/revolution mechanism and includes a bearing member 13 provided in a circular opening formed on a disk-shaped susceptor 12, a soaking plate 14 mounted rotatably on the bearing member, an external gear member 15 mounted on the soaking plate, a ring-shaped fixed internal gear member 17 including an internal gear engaged with the external gear member, a heating unit 19 for heating a substrate 18 retained on the external gear member from a backside of the susceptor, and a flow channel 20 for guiding a raw material gas in a direction parallel to a surface of the substrate. An external diameter of the bearing member or a gear reference circle diameter of the external gear member is smaller than an external diameter of the substrate.

### TECHNICAL FIELD

The present invention relates to a vapor phase growth apparatus, and in particular relates to a rotation/revolution type vapor phase growth apparatus that performs vapor-phase growth of a thin film, particularly, of a nitride-based compound semiconductor thin film on a surface of a substrate while rotating/revolving the substrate.

### BACKGROUND ART

As a vapor phase growth apparatus that allows for vapor phase growth on multiple substrates at a time, there is known a rotation/revolution type vapor phase growth apparatus in which a plurality of rotation susceptors with a soaking plate are arranged in a circumferential direction of an outer periphery of a revolution susceptor, and a bearing and an external gear are provided at outer peripheries of the rotation susceptors with the soaking plate to engage an internal gear provided inside a reactor vessel with the external gear, thereby rotating/revolving the substrates during deposition (for example, see Patent Document 1).

### PRIOR ART REFERENCE

### Patent Document

Patent Document 1: JP 2007-266121 A

### SUMMARY OF THE INVENTION

### Problems to be Solved by the Invention

However, in the rotation/revolution type vapor phase growth apparatus described in Patent Document 1 above, the bearing is arranged more externally than the substrate outer periphery. Thus, a minimum external diameter of the rotation susceptors is equivalent to the size of a substrate external diameter plus a bearing size. This leads to the limitation of the number of the rotation susceptors arranged at the outer periphery of the revolution susceptor. Accordingly, processing of multiple pieces of substrate requires the use of a revolution susceptor having a large diameter, resulting in upsizing of a flow channel and a chamber, which causes a problem of increasing the amount of a raw material gas to be used.

Therefore, it is an object of the present invention to provide a rotation/revolution type vapor phase growth apparatus capable of increasing the area of a semiconductor thin film that can be vapor-phase grown at a time, without upsizing a susceptor or the like.

### Means for Solving the Problem

To achieve the above object, a first structure of the vapor phase growth apparatus of the present invention is a horizontal vapor phase growth apparatus having a rotation/revolution mechanism, including a disk-shaped susceptor provided rotatably in a chamber, a ring-shaped bearing member provided each in a plurality of circular openings formed in a circumferential direction of an outer periphery of the susceptor, a disk-shaped soaking plate mounted each rotatably on the each bearing member, an external gear member mounted each on the each soaking plate, a ring-shaped fixed internal gear member including an internal gear engaged with the external gear member, a heating unit for heating a substrate retained on a surface of the external gear member from a backside of the susceptor, and a flow channel for guiding a raw material gas in a direction parallel to a surface of the substrate, in which the bearing member has an external diameter smaller than an external diameter of the substrate.

In addition, a second structure of the vapor phase growth apparatus of the present invention is a horizontal vapor phase growth apparatus having a rotation/revolution mechanism, including a disk-shaped susceptor provided rotatably in a chamber, a ring-shaped bearing member provided each in a plurality of circular openings formed in a circumferential direction of an outer periphery of the susceptor, a disk-shaped soaking plate mounted each rotatably on the each bearing member, an external gear member mounted each on the each soaking plate, a ring-shaped fixed internal gear member including an internal gear engaged with the external gear member, a heating unit for heating a substrate retained on a surface of the external gear member from a backside of the susceptor, and a flow channel for guiding a raw material gas in a direction parallel to a surface of the substrate, in which the external gear member has a gear reference circle diameter smaller than an external diameter of the substrate.

In addition, in the first structure and the second structure of the vapor phase growth apparatus of the present invention, a soaking space portion is provided between the soaking plate and the external gear member, and a nitride-based compound semiconductor thin film can be grown on the surface of the substrate.

### Effects of the Invention

According to the vapor phase growth apparatus of the present invention, the external diameter of the bearing member or the gear reference circle diameter of the external gear member is made smaller than the external diameter of the substrate. This can increase the number of substrate pieces that can be processed at a time, without upsizing the susceptor or the like, thus allowing for a significant increase in the area of the semiconductor thin film that can be vapor-phase grown at a time.

### BRIEF DESCRIPTION OF THE DRAWINGS

FIG. 1 is a sectional front view showing an embodiment example of a vapor phase growth apparatus according to the present invention.

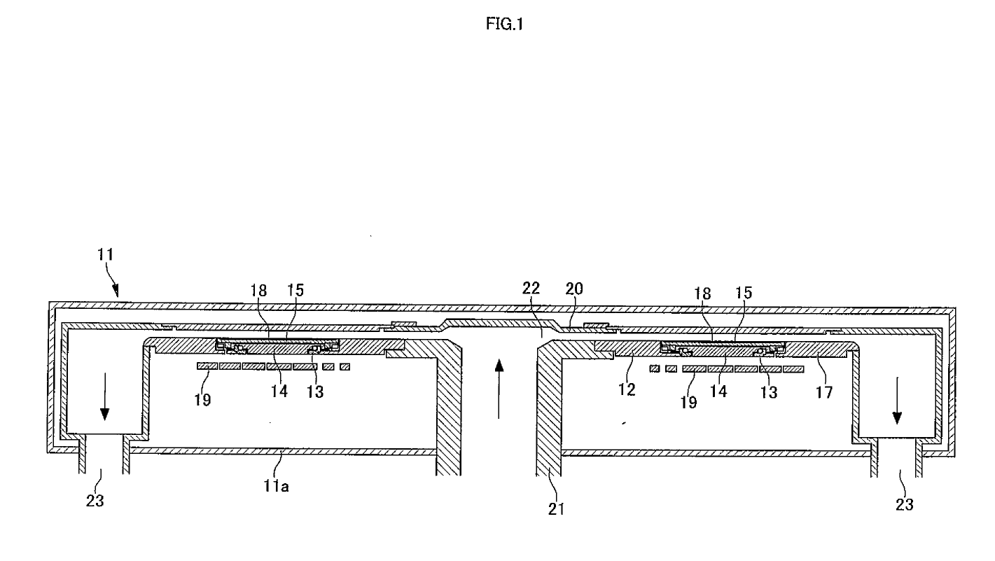

FIG. 2 is a sectional front view of a main part of the embodiment example thereof.

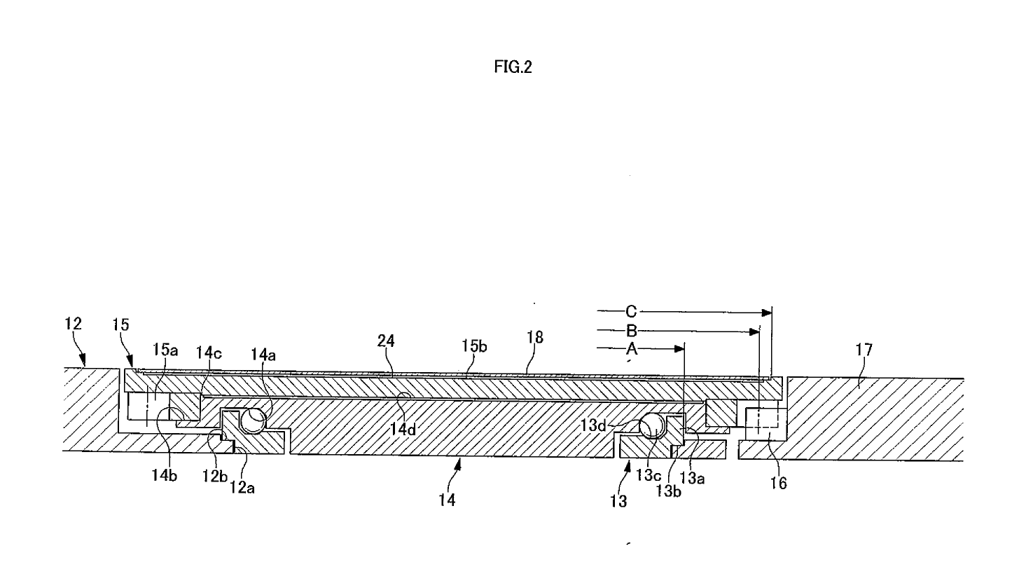

FIG. 3 is a sectional front view showing separated respective members of the embodiment example thereof.

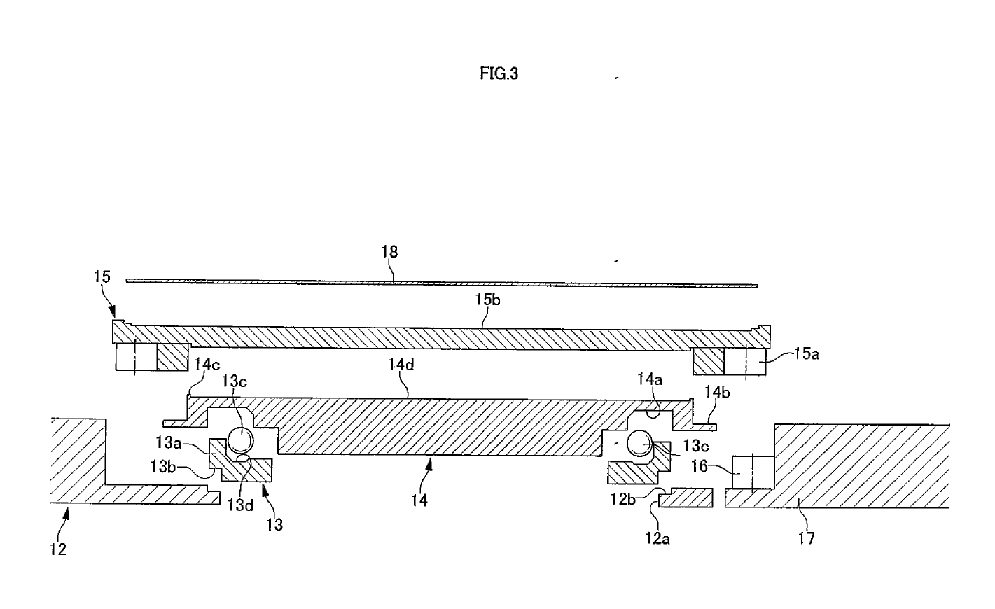

FIG. 4 is illustrative views comparing the number of substrate pieces that can be vapor-phase grown at a time.

FIG. 5 is a view comparing upper surface temperatures of an external gear member.

### MODES FOR CARRYING OUT THE INVENTION

A vapor phase growth apparatus shown in the present embodiment example includes a disk-shaped susceptor 12 provided rotatably in a chamber 11, a ring-shaped bearing member 13 provided each in a plurality of circular openings 12a formed in a circumferential direction of an outer periphery of the susceptor 12, a disk-shaped soaking plate 14 mounted each rotatably on the each bearing member 13, an external gear member (a rotation susceptor) 15 mounted each on the each soaking plates 14, a ring-shaped fixed internal gear member 17 including an internal gear 16 engaged with the external gear member 15, a heating unit (a heater) 19 for heating a substrate 18 retained on a surface of the external gear member 15 from a backside of the susceptor 12, and a flow channel 20 for guiding a raw material gas in a direction parallel to a surface of the substrate 18.

In the middle of the susceptor 12 is provided a hollow shaft member 21 extended downward the susceptor 12 to penetrate through a bottom plate 11a of the chamber 11. An inner part of the hollow shaft member 21 is used as a raw material gas passage, and at a lower part of the hollow shaft member 21 is provided a driving unit (not shown) for rotating the susceptor 12 via the hollow shaft member 21. Furthermore, at an upper end of the hollow shaft member 21 is provided a gas guiding portion 22 for guiding the raw material gas into the flow channel 20, and at an outer periphery of the flow channel 20 are provided a plurality of gas exhausting portions 23.

The bearing member 13 is formed into an L-letter shape in its cross section having a rising portion 13a at its outer periphery. At a lower surface outer periphery of the bearing member 13 is provided a downward engaging step portion 13b corresponding to an upward engaging step portion 12b provided at an opening edge of the circular opening 12a. On an upper surface of an inner peripheral side of the rising portion 13a is provided a circumferential groove 13d for retaining a plurality of rolling members (balls) 13c.

Additionally, the soaking plate 14 has a ring-shaped accommodation groove 14a for accommodating the bearing member 13 in a circumference direction of a lower surface outer periphery thereof and has an upward engaging step portion 14b for mounting the external gear member 15 at an outer periphery thereof. Furthermore, at an upper surface outer periphery of the soaking plate 14 is provided a small projection 14c having a ring shape, and on an inner peripheral side of the small projection 14c is formed a circular concave-shaped portion 14d surrounded by the small projection 14c.

The external gear member 15 has a ring-shaped external gear portion 15a provided at a lower surface outer periphery thereof. The external gear portion 15a has an inner diameter and a height (thickness) whose sizes are corresponding to the engaging step portion 14b of the soaking plate 14. In addition, on an upper surface of the external gear member 15 is provided a concave portion 15b retaining the substrate 18.

Under a state in which the bearing member 13, the soaking plate 14 and the external gear member 15 are assembled together and the substrate 18 is retained on the external gear member 15, the lower surface of the bearing member 13 and the lower surface of the soaking plate 14 are formed to be flush with a lower surface of the susceptor 12 and an outer peripheral upper surface of the external gear member 15 and an upper surface of the substrate 18 are formed to be flush with an upper surface of the susceptor 12.

Additionally, in the present embodiment example, an external diameter A of the bearing member 13 and a gear reference circle diameter B of the external gear portion 15a of the external gear member 15 are set to have a size smaller than an external diameter C of the substrate 18. In other words, the external gear portion 15a is provided at the lower surface outer periphery of the external gear member 15 retaining the substrate 18 and in such a manner that its addendum circle is positioned on an inner peripheral side of an outer peripheral edge of the external gear member 15, whereby an outer peripheral portion of the substrate retaining portion 15b provided on the surface side of the external gear member 15 defines a maximum external diameter of the external gear member 15.

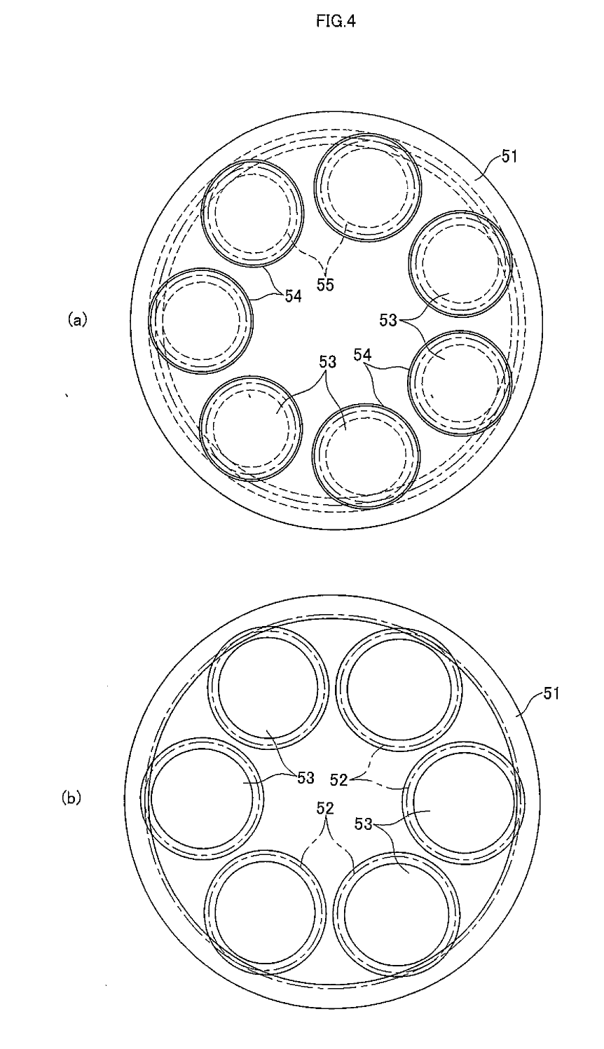

As described above, the outer peripheral portion of the substrate retaining portion 15b is the maximum external diameter in the external gear member 15. Thus, for example, as shown by the comparison between FIG. 4(a) and FIG. 4(b), in a case of using susceptors 51 having the same diameter, FIG. 4(b) shows that only six pieces of a substrate 53 can be simultaneously processed in a conventional structure in which an external gear 52 is positioned at the most outer periphery. On the other hand, as in FIG. 4(a), when employing the foregoing structure in which a substrate retaining portion 54 is positioned at the most outer periphery and an external gear 55 is positioned at the inner periphery, seven pieces of the same substrate 53 can be simultaneously processed, so that the area of a semiconductor thin film that allows for deposition at a time can be significantly increased.

In addition, as shown in the present embodiment example, the small projection 14c is provided on the upper surface outer periphery of the soaking plate 14 and the concave-shaped portion 14d is formed on the inner peripheral side of the small projection 14c. Thereby, between the upper surface of the soaking plate 14 and the lower surface of the external gear member 15 can be formed a soaking space portion 24 for equalizing a temperature of the external gear member 15, that is, a surface temperature of the substrate 18 retained on the upper surface of the external gear member 15.

Even if the shape, structure, material and the like of the external gear member 15, the soaking plate 14 and the bearing member 13 are different, the formation of the soaking space portion 24 can equalize the amount of heat transmitted to the substrate 18 through them from the heating unit 19 provided below, so that temperature distribution of the surface of the substrate 18 can be reduced, thereby allowing for the uniformity of a semiconductor thin film formed on the surface of the substrate 18.

For example, in the case of a nitride-based compound semiconductor thin film, particularly, in the growth of an InGaN thin film that is a material of blue LED, a compositional stability condition range in crystal growth is extremely narrow and the thin film is regarded as a light emitting layer most sensitive to growth temperature. Therefore, desirably, the temperature distribution on the surface of the substrate 18 is made small, that is, an InGaN thin film is grown at a uniform substrate temperature.

Additionally, measuring the temperature distribution in the state in which the respective members are produced and assembled together to adjust a depth of the concave-shaped portion 14d with respect to the small projection 14c and a surface condition of the concave-shaped portion 14d can lead to the optimization of the soaking space portion 24. Thereby, not only the temperature difference of a single substrate but also the temperature difference between a plurality of substrates to be simultaneously processed can be eliminated.

Thereby, even if the external diameter A of the bearing member 13 and the gear reference circle diameter B of the external gear portion 15a of the external gear member 15 is set to be smaller than the external diameter C of the substrate 18, a uniform semiconductor thin film can be efficiently and stably obtained. Particularly, in the case of vapor-phase growing a nitride-based compound semiconductor thin film in which the heating temperature of the substrate 18 is high and the temperature difference of the substrate surface easily causes variation in the properties of a semiconductor thin film formed, the formation of the soaking space portion 24 allows for the production of a uniform and high-quality nitride-based compound semiconductor thin film.

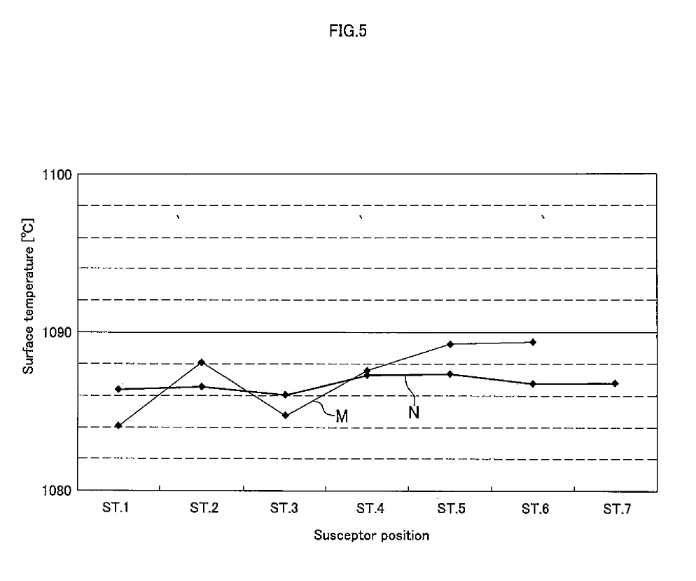

FIG. 5 shows an example of results obtained by measuring the temperature distribution of the upper surface (the surface in contact with the substrate 18) of the external gear member 15 corresponding to a center of the substrate 18. In the temperature distribution obtained when the soaking space portion 24 was not provided, as shown by Line M, a temperature difference of 5.3° C. occurred. On the other hand, in the temperature distribution obtained when the soaking space portion 24 was provided, as shown by Line N, the temperature difference was 1.3° C. This indicates that the temperature difference can be reduced by the soaking space portion 24.

Furthermore, in each susceptor position, respective upper surface temperatures of the external gear member 15 corresponding to two points at distances of ±30 mm from the center of the substrate 18 were also measured. As a result, the temperature difference between a temperature of the upper surface of the external gear member 15 corresponding to the center of the substrate 18 and the temperatures of the upper surface of the external gear member 15 corresponding to the two points at the distances of ±30 mm from the center thereof was approximately 2° C. at a maximum, so that temperature uniformity of each substrate was also maintained.

### REFERENCE NUMERALS

11 . . . chamber

11a . . . bottom plate

12 . . . susceptor

12a . . . circular opening

12b . . . engaging step portion

13 . . . bearing member

13a . . . rising portion

13b . . . engaging step portion

13c . . . rolling member

13d . . . circumferential groove

14 . . . soaking plate

14a . . . accommodation groove

14b . . . engaging step portion

14c . . . small projection

14d . . . concave-shaped portion

15 . . . external gear member

15a . . . external gear portion

15b . . . concave portion

16 . . . internal gear

17 . . . fixed internal gear member

18 . . . substrate

19 . . . heating unit

20 . . . flow channel

21 . . . hollow shaft member

22 . . . gas guiding portion

23 . . . gas exhausting portion

24 . . . soaking space portion

51 . . . susceptor

52 . . . external gear

53 substrate

54 . . . substrate retaining portion

55 . . . external gear

A . . . external diameter of bearing member 13

B . . . gear reference circle diameter of external gear portion 15a

C . . . external diameter of substrate 18

1. A vapor phase growth apparatus that is a horizontal vapor phase growth apparatus having a rotation/revolution mechanism, the apparatus comprising a disk-shaped susceptor provided rotatably in a chamber, a ring-shaped bearing member provided each in a plurality of circular openings formed in a circumferential direction of an outer periphery of the susceptor, a disk-shaped soaking plate mounted each rotatably on the each bearing member, an external gear member mounted each on the each soaking plate, a ring-shaped fixed internal gear member including an internal gear engaged with the external gear member, a heating unit for heating a substrate retained on a surface of the external gear member from a backside of the susceptor, and a flow channel for guiding a raw material gas in a direction parallel to a surface of the substrate, wherein the bearing member has an external diameter smaller than an external diameter of the substrate.

2. A vapor phase growth apparatus that is a horizontal vapor phase growth apparatus having a rotation/revolution mechanism, the apparatus comprising a disk-shaped susceptor provided rotatably in a chamber, a ring-shaped bearing member provided each in a plurality of circular openings formed in a circumferential direction of an outer periphery of the susceptor, a disk-shaped soaking plate mounted each rotatably on the each bearing member, an external gear member mounted each on the each soaking plate, a ring-shaped fixed internal gear member including an internal gear engaged with the external gear member, a heating unit for heating a substrate retained on a surface of the external gear member from a backside of the susceptor, and a flow channel for guiding a raw material gas in a direction parallel to a surface of the substrate, wherein the external gear member has a gear reference circle diameter smaller than an external diameter of the substrate.

3. The vapor phase growth apparatus according to claim 1, wherein a soaking space portion is provided between the soaking plate and the external gear member.

4. The vapor phase growth apparatus according to claim 1, wherein a nitride-based compound semiconductor thin film is grown on the surface of the substrate.

5. The vapor phase growth apparatus according to claim 2, wherein a soaking space portion is provided between the soaking plate and the external gear member.

6. The vapor phase growth apparatus according to claim 2, wherein a nitride-based compound semiconductor thin film is grown on the surface of the substrate.

7. The vapor phase growth apparatus according to claim 3, wherein a nitride-based compound semiconductor thin film is grown on the surface of the substrate.

8. The vapor phase growth apparatus according to claim 5, wherein a nitride-based compound semiconductor thin film is grown on the surface of the substrate.
